(19) United States
(12) Patent Application Publication
(10) Pub. No.: US 2021/0005477 A1
(43) Pub. Date: Jan. 7, 2021

(54) SUBSTRATE PROCESSING APPARATUS

(71) Applicant: Tokyo Electron Limited, Tokyo (JP)

(72) Inventors: Ryou Son, Miyagi (JP); Sinya Sasaki, Miyagi (JP); Hiroyuki Kondo, Miyagi (JP); Syuntaro Tamaraya, Miyagi (JP); Takaaki Kikuchi, Miyagi (JP)

(21) Appl. No.: 16/910,575

(22) Filed: Jun. 24, 2020

(30) Foreign Application Priority Data
Jul. 5, 2019 (JP) 2019-126422
Mar. 24, 2020 (JP) 2020-053291

(51) Int. Cl. H01L 21/67; C23C 16/48; C23C 16/44; C23C 16/458

(52) U.S. Cl. CPC H01L 21/67098; C23C 16/481; H01L 21/6719; C23C 16/4586; C23C 16/4404

(57) ABSTRACT

A substrate processing apparatus includes an inner wall formed of a heat conductive material, a quartz liner that covers the inner wall, and a cooling unit that cools the inner wall. A gap is formed between the inner wall and the quartz liner, and a sealing member is provided in the gap to seal the gap. The gap is filled with a heat conductive medium.

### CROSS-REFERENCE TO RELATED APPLICATIONS

This patent application is based upon and claims priority to Japanese Patent Application No. 2019-126422 filed on Jul. 5, 2019, and Japanese Patent Application No. 2020-053291 filed on Mar. 24, 2020, the entire contents of which are incorporated herein by reference.

### TECHNICAL FIELD

The present disclosure relates to a substrate processing apparatus.

### BACKGROUND

For example, there is known a substrate processing apparatus that applies a predetermined process on a substrate such as a wafer.

Patent Document 1 describes a plasma processing apparatus including a vacuum vessel. In the vacuum vessel of the plasma processing apparatus, a hollow cylindrical inner wall member made of aluminum and a quartz cover disposed inside the inner wall member are provided.

Patent Document 2 describes that when SiO₂ is used as a material of the inner wall, an etching rate of a substrate varies depending on the wall temperature.

### RELATED ART DOCUMENTS

### Patent Documents

[Patent Document 1] Japanese Laid-open Patent Application Publication No. 2008-251857

[Patent Document 2] Japanese Laid-open Patent Application Publication No. 2002-319577

### SUMMARY

In one aspect, the present disclosure provides a substrate processing apparatus that suitably controls the temperature of the inner wall surface.

In order to solve the above-described problem, according to one aspect, a substrate processing apparatus is provided that includes an inner wall formed of a heat conductive material, a quartz liner that covers the inner wall, and a cooling unit that cools the inner wall. A gap is formed between the inner wall and the quartz liner, and a sealing member is provided in the gap to seal the gap. The gap is filled with a heat conductive medium.

### BRIEF DESCRIPTION OF THE DRAWINGS

FIG. 1 is a schematic diagram illustrating a plasma processing apparatus according to a first embodiment;

FIG. 2 is an enlarged cross-sectional view schematically illustrating an example of a part of the plasma processing apparatus according to the first embodiment;

FIG. 3 is an enlarged cross-sectional view schematically illustrating an example of another part of the plasma processing apparatus according to the first embodiment;

FIG. 4 is an enlarged cross-sectional view schematically illustrating an example of a part of a plasma processing apparatus according to a second embodiment; and

FIG. 5 is an enlarged cross-sectional view schematically illustrating an example of a part of a plasma processing apparatus according to a third embodiment.

### DETAILED DESCRIPTION OF EMBODIMENTS

In the following, various exemplary embodiments will be described in detail with reference to the drawings. Note that in the drawings, elements having substantially identical features are given the same reference symbols.

### First Embodiment

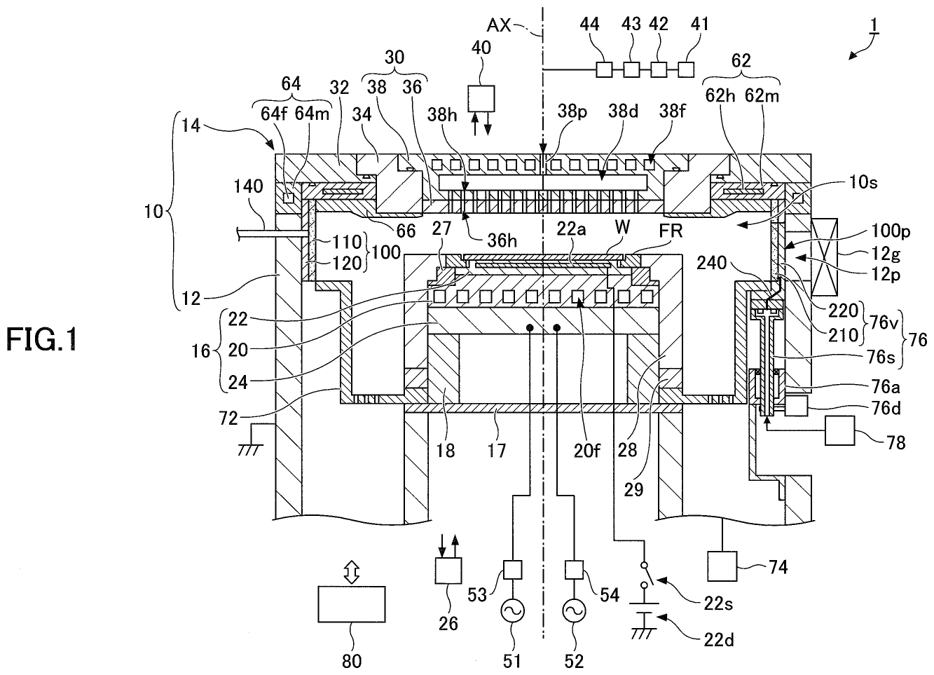

A plasma processing apparatus (substrate processing apparatus) 1 according to a first embodiment will be described with reference to FIG. 1. FIG. 1 is a cross-sectional diagram illustrating an example of the plasma processing apparatus 1 according to the first embodiment.

The plasma processing apparatus 1 includes a chamber 10. The chamber 10 provides an interior space 10s therein. The interior space 10s can be decompressed. A plasma is formed in the interior space 10s.

The chamber 10 includes a chamber body 12 and a top section 14. The chamber body 12 forms a side wall and a bottom surface of the chamber 10. The chamber body 12 has a generally cylindrical shape. The central axis of the chamber body 12 is substantially coincident with an axis line AX illustrated in FIG. 1 that extends vertically. The chamber body 12 is electrically grounded. The chamber body 12 is formed of, for example, aluminum. A corrosion resistant film is formed on the surface of the chamber body 12. The corrosion resistant film is formed of a material such as aluminum oxide or yttrium oxide.

An opening 12p is formed in the side wall of the chamber 10. The opening 12p is provided on the chamber body 12. The opening 12p can be opened and closed by a gate valve 12g. When a substrate W (may also be referred to as a “wafer W”) is conveyed between the interior space 10s and the exterior of the chamber 10, the substrate W passes through the opening 12p.

A support platform 16 is provided in the interior space 10s. The support platform 16 is configured to support the substrate W, which is placed on the support platform 16. A bottom plate 17 is provided below the support platform 16. The bottom plate 17 is supported by the bottom of the chamber 10. From the bottom plate 17, a support 18 extends upward. The support 18 has a generally cylindrical shape. The support 18 is formed of an insulating material such as quartz. The support platform 16 is mounted on the support 18, and is supported by the support 18.

The support platform 16 includes a lower electrode 20 and an electrostatic chuck 22. The support platform 16 may further include an electrode plate 24. The electrode plate 24 has a general disc shape. The central axis of the electrode plate 24 is substantially coincident with the axis line AX. The electrode plate 24 is formed of a conductor such as aluminum.

The lower electrode 20 is provided on the electrode plate 24. The lower electrode 20 is electrically connected to the electrode plate 24. The lower electrode 20 has a general disc shape. The central axis of the lower electrode 20 is substantially coincident with the axis line AX. The lower electrode 20 is formed from a conductor such as aluminum. A flow passage 20f is formed in the lower electrode 20. The flow passage 20f extends spirally for example. Coolant is supplied to the flow passage 20f from a chiller unit 26. The chiller unit 26 is provided outside the chamber 10. The chiller unit 26 supplies, for example, liquid coolant to the flow passage 20f. The coolant supplied to the flow passage 20f is returned to the chiller unit 26.

The electrostatic chuck 22 is provided on the lower electrode 20. The electrostatic chuck 22 includes a body and an electrode 22a. The body of the electrostatic chuck 22 has a general disc shape. The central axis of the electrostatic chuck 22 substantially coincides with the axis line AX. The body of the electrostatic chuck 22 is formed of ceramic. The electrode 22a is a film formed from a conductor. The electrode 22a is provided within the body of the electrostatic chuck 22. A direct-current (DC) power supply 22d is coupled to the electrode 22a via a switch 22s. When the electrostatic chuck 22 is caused to hold the substrate W, voltage is applied to the electrode 22a from the DC power supply 22d. When voltage is applied to the electrode 22a, electrostatic attractive force is generated between the electrostatic chuck 22 and the substrate W. The substrate W is attracted to the electrostatic chuck 22 by the generated electrostatic attractive force, and is held by the electrostatic chuck 22. The plasma processing apparatus 1 may include a gas line to supply a heat transfer gas (e.g., helium gas) between the electrostatic chuck 22 and the back surface of the substrate W.

A focus ring FR is disposed on the periphery of the electrostatic chuck 22 so as to surround the substrate W. The focus ring FR improves in-plane uniformity of a plasma process applied to the substrate W. The focus ring FR may be formed of, for example, silicon, quartz, or silicon carbide. A ring 27 is provided between the focus ring FR and the lower electrode 20. The ring 27 is formed of an insulating material.

The plasma processing apparatus 1 may further include a cylindrical member 28 and a cylindrical member 29. The cylindrical member 28 extends along outer circumferences of the support platform 16 and the support 18. The cylindrical member 28 is provided on the cylindrical member 29. The cylindrical member 28 is formed of a corrosion-resistant insulating material. The cylindrical member 28 is formed of quartz, for example. The cylindrical member 29 extends along the outer circumference of the support 18. The cylindrical member 29 is formed of a corrosion-resistant insulator. The cylindrical member 29 is formed of quartz, for example.

The top section 14 is provided to occlude an opening at the upper end of the chamber 10. The top section 14 includes an upper electrode 30. The top section 14 may further include a member 32 and a member 34. The member 32 is a generally annular plate, and is formed of metal such as aluminum. The member 32 is provided on the side wall of the chamber 10 via a member 64. Details of the member 64 will be described below. The member 34 is provided between the upper electrode 30 and the member 32. The member 34 extends circumferentially with respect to the axis line AX. The member 34 is formed of an insulator such as quartz.

The upper electrode 30 includes a top plate 36 and a support 38. The top plate 36 has a general disc shape. The bottom surface of the top plate 36 is exposed to the interior space 10s. Multiple gas discharge holes 36h are formed in the top plate 36. The multiple gas discharge holes 36h penetrate the top plate 36 in the plate thickness direction (vertical direction). The top plate 36 may be made of silicon, aluminum oxide, or quartz. Alternatively, the top plate 36 may be formed of a conductive member, such as aluminum, whose surface is covered with a corrosion resistant film. The corrosion resistant film is formed of a material such as aluminum oxide or yttrium oxide.

The support 38 is provided on the top plate 36. The support 38 detachably supports the top plate 36. The support 38 is formed of aluminum, for example. A flow passage 38f is formed in the support 38. The flow passage 38f extends, for example, spirally in the support 38. Coolant is supplied to the flow passage 38f from a chiller unit 40. The chiller unit 40 is provided outside the chamber 10. The chiller unit 40 supplies liquid coolant (e.g., cooling water) to the flow passage 38f. The coolant supplied to the flow passage 38f is returned to the chiller unit 40. The chiller unit 40 may supply coolant to the flow passage 38f at a flow rate of, for example, 4 L/min or greater.

A gas diffusion chamber 38d is formed within the support 38. Multiple holes 38h are formed in the support 38. The multiple holes 38h extend downward from the gas diffusion chamber 38d, and are respectively connected to the multiple gas discharge holes 36h. The support 38 is provided with a port 38p. The port 38p is connected to the gas diffusion chamber 38d. Gas sources 41 are connected to the port 38p via valves 42, flow controllers 43, and valves 44.

Each of the flow controllers 43 is a mass flow controller or a pressure-controlled flow controller. Each of the gas sources 41 is connected to the port 38p via a corresponding valve in the valves 44, a corresponding flow controller in the flow controllers 43, and a corresponding valve in the valves 42. In the plasma processing apparatus 1, gas is supplied to the gas diffusion chamber 38d from one or more gas sources that are selected from the gas sources 41. The gas supplied to the gas diffusion chamber 38d is supplied to the interior space 10s from the multiple gas discharge holes 36h.

The plasma processing apparatus 1 further includes a first radio frequency power supply 51 and a second radio frequency power supply 52. The first radio frequency power supply 51 is a power supply that generates first radio frequency electric power for plasma generation. The frequency of the first radio frequency electric power is, for example, 27 MHz or greater. The first radio frequency power supply 51 is electrically coupled to the lower electrode 20 via a matcher 53. The matcher 53 includes matching circuitry to cause load impedance (input impedance on the lower electrode 20 side) to match output impedance of the first radio frequency power supply 51. The first radio frequency power supply 51 may be coupled to the upper electrode 30 via the matcher 53 rather than the lower electrode 20.

The second radio frequency power supply 52 is a power supply that generates second radio frequency electric power for attracting ions to the substrate W. The frequency of the second radio frequency electric power is, for example, 13.56 MHz or less. The second radio frequency power supply 52 is electrically coupled to the lower electrode 20 via a matcher 54. The matcher 54 includes matching circuitry for causing load impedance (input impedance on the lower electrode 20 side) to match output impedance of the second radio frequency power supply 52.

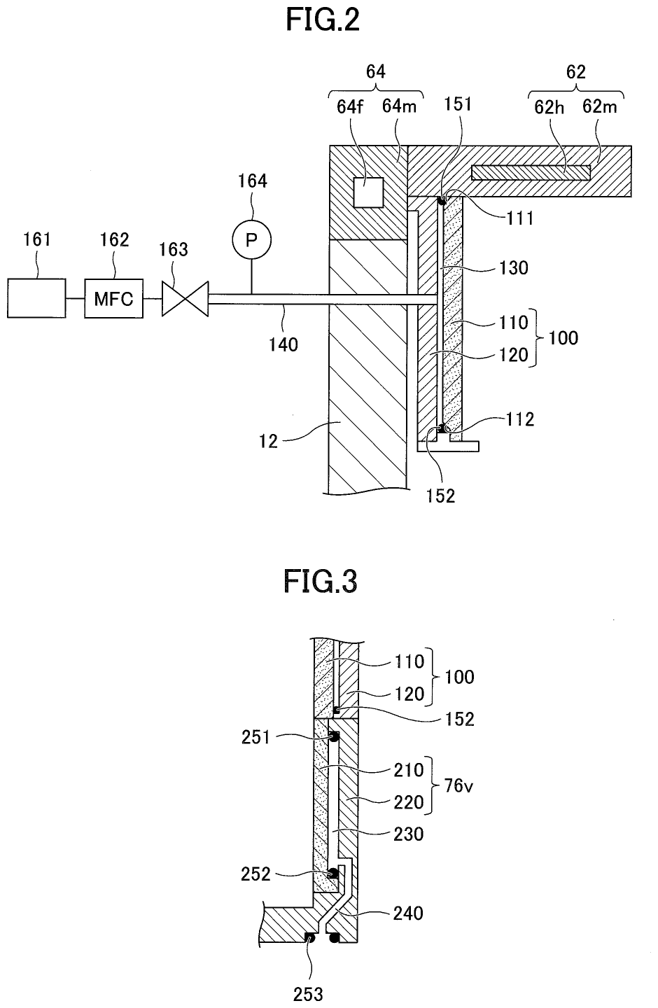

The plasma processing apparatus 1 further includes a deposition shield 100 which inhibits by-products of plasma processing from depositing on the inner wall surface of the chamber 10. The deposition shield 100 has a generally cylindrical shape, and is disposed along the inner wall surface of the chamber 10 (chamber body 12). The inner wall surface of the deposition shield 100 is exposed to the interior space 10s, and is exposed to plasma. Further, an opening 100p is formed in the deposition shield 100. The opening 100p is formed in the deposition shield 100 such that the opening 100p faces the opening 12p. When the substrate W is conveyed between the interior space 10s and the exterior of the chamber 10, the substrate W passes through the opening 12p and the opening 100p. The structure of the deposition shield 100 will be described further below with reference to FIG. 2.

The plasma processing apparatus 1 further includes the member 64 (water cooling unit) that cools (removes heat from) the deposition shield 100. The member 64 has a generally annular shape in a top view (a view seen from a direction of the axis line AX), and a cross-section of the member 64 is generally rectangular. The member 64 is sandwiched between the chamber body 12 and the top section 14 (member 32). The member 64 is also in contact with the deposition shield 100 such that heat can be conducted between the member 64 and the deposition shield 100. In the example of FIG. 1, the lower side of the inner circumferential surface of the member 64 is in thermal contact with the upper side of the outer circumferential surface of the deposition shield 100. The member 64 includes a body 64m and a flow passage 64f. The body 64m is formed of, for example, aluminum. The flow passage 64f extends around the generally annular member 64 within the member 64. Coolant is supplied to the flow passage 64f from the chiller unit 40. The chiller unit 40 supplies liquid coolant (e.g., cooling water) to the flow passage 64f. The coolant supplied to the flow passage 64f is returned to the chiller unit 40. The chiller unit 40 may supply coolant to the flow passage 64f at a flow rate of, for example, 4 L/min or greater.

The plasma processing apparatus 1 further includes a heater unit 62 (see also FIG. 2) that heats the deposition shield 100. The heater unit 62 has a generally annular shape in the top view, and a cross-section of the heater unit 62 is generally rectangular. The heater unit 62 circumferentially extends so as to surround the upper electrode 30. The heater unit 62 is disposed, in a radial direction, outside the member 34 and inside the member 64, and is disposed, in the vertical direction, under the member 32 and on a member 66 which will be discussed below. The heater unit 62 is also thermally in contact with the member 64 and the deposition shield 100 in the example of FIG. 1 or 2, the outer side surface of the heater unit 62 is in thermal contact with the upper side of the inner side surface of the member 64, and the lower surface of the heater unit 62 is in thermal contact with the upper surface of the deposition shield 100. The heater unit 62 includes a body 62m and a heater 62h. The body 62m is formed of, for example, aluminum. The heater 62h is, for example, a resistive heating element.

The top section 14 of the plasma processing apparatus 1 further includes the member 66. The member 66 is a generally annular plate. The member 66 circumferentially extends in an outer peripheral region of the top plate 36. The member 66 is exposed to the interior space 10s and is exposed to plasma.

A baffle member 72 is provided between the deposition shield 100 and the support 18. The baffle member 72 has a generally cylindrical shape. At the upper end of the baffle member 72, a flange is provided. The bottom of the baffle member 72 is formed in a generally annular shape, and extends inward in a radial direction. The flange provided at the upper end of the baffle member 72 is connected to the lower end of the deposition shield 100. The inner edge of the lower end of the baffle member 72 is sandwiched between the cylindrical member 29 and the bottom plate 17. The baffle member 72 is formed of a conductive plate such as aluminum. A corrosion resistant film is formed on a surface of the baffle member 72. The corrosion resistant film may be formed of a material such as aluminum oxide or yttrium oxide. Multiple through-holes are formed in the baffle member 72.

An exhaust device 74 is connected to an exhaust area extending below the baffle member 72. The exhaust device 74 includes a pressure regulator such as an automatic pressure control valve, and a vacuum pump such as a turbomolecular pump.

The plasma processing apparatus 1 may further include a shutter mechanism 76. The shutter mechanism 76 is configured to open and close the opening 100p. The shutter mechanism 76 includes a valve body (shutter) 76v and an axial member 76s. The shutter mechanism 76 may further include a cylinder 76a and an actuator 76d.

The valve body 76v occludes the opening 100p in a state in which the valve body 76v is positioned at the opening 100p. The valve body 76v is supported by the axial member 76s. In a state in which the valve body 76v occludes the opening 100p, the valve body 76v abuts the deposition shield 100, and a cylindrical surface is formed by the inner circumferential wall surface of the deposition shield 100 and the inner circumferential surface of the valve body 76v. The axial member 76s is connected to the bottom of the valve body 76v, and extends downward to penetrate the bottom surface of the chamber body 12. The cylinder 76a is fixed to the chamber body 12. The axial member 76s is inserted into the cylinder 76a. The cylinder 76a is provided with a sealing member (not illustrated) that seals a gap between the cylinder 76a and the axial member 76s. This ensures airtightness of the interior space 10s. The actuator 76d can open and close the opening 100p of the deposition shield 100 by moving the axial member 76s up and down to raise and lower the valve body 76v.

The plasma processing apparatus 1 further includes a feeder 78. The feeder 78 supplies a heat conductive medium (e.g., an inert gas such as helium, nitrogen and argon, or a dry air) to the axial member 76s.

The plasma processing apparatus 1 may further include a controller 80. The controller 80 is configured to control each portion of the plasma processing apparatus 1. The controller 80 may be, for example, a computing device. The controller 80 includes a processor, a storage device, an input device such as a keyboard, a display device, and a signal input/output (I/O) interface. A control program and recipe data are stored in the storage device. The processor executes the control program, and transmits control signals via the I/O interface to each portion of the plasma processing apparatus 1 in accordance with the recipe data.

Next, the structure of the deposition shield 100 will be further described with reference to FIG. 2. FIG. 2 is an enlarged cross-sectional view schematically illustrating an example of a part of the plasma processing apparatus 1 according to the first embodiment.

As illustrated in FIG. 2, the deposition shield 100 includes a first deposition shield 110 of a generally cylindrical shape and a second deposition shield 120 of a generally cylindrical shape. The second deposition shield 120 is formed of a heat conductive material having high thermal conductivity, e.g., metal such as aluminum, and is disposed along an inner circumferential surface of the chamber 10 (chamber body 12). The second deposition shield 120 is also disposed such that the second deposition shield 120 is in thermal contact with the heater unit 62 and the member (water cooling unit) 64. The first deposition shield 110 is a liner (may also be referred to as a “quartz liner”) formed of a material having a lower thermal conductivity than the second deposition shield 120, e.g., ceramic such as quartz (SiO₂). The first deposition shield 110 is disposed along an inner circumferential surface of the second deposition shield 120. The inner circumferential surface of the first deposition shield 110 is exposed to the interior space 10s, in which a plasma is generated. Hereinafter, the first deposition shield 110 will be described as being formed of quartz and the second deposition shield 120 as being formed of aluminum.

The first deposition shield 110 is inserted into the inner periphery of the second deposition shield 120, in a manner in which the first deposition shield 110 is removable (replaceable). Therefore, a gap 130 is formed between the first and second deposition shields 110 and 120.

Also, the deposition shield 100 expands by heat of a plasma generated in the interior space 10s. In this case, because the thermal expansion coefficient of quartz is smaller than that of aluminum, an amount of thermal expansion of the first deposition shield 110 provided inside the second deposition shield 120 is smaller than that of the second deposition shield 120. Therefore, the gap 130 is formed between the first and second deposition shields 110 and 120 to absorb the difference in the amount of thermal expansion. As the first and second deposition shields 110 and 120 expand by heat, the gap 130 expands radially due to the difference in the amount of thermal expansion between the first and second deposition shields 110 and 120. It is preferable that the gap between the first and second deposition shields 110 and 120 is, for example, greater than or equal to 0.2 mm and less than or equal to 3.0 mm, before the first and second deposition shields 110 and 120 expand by heat of a plasma.

A supply line 140 passes through the chamber body 12 and the second deposition shield 120, and communicates with the gap 130. Gas serving as a heat conductive medium is supplied through the supply line 140, and the gap 130 is filled with the heat conductive medium. Here, for example, helium gas may be used as the heat conductive medium. Alternatively, the gas filled in the gap 130 as the heat conductive medium may be dry air or an inert gas such as argon or nitrogen. In addition to the supply line 140 for supplying the gas to the gap 130, a drain tube (not illustrated) for discharging the gas supplied to the gap 130 may be provided. In addition, gas discharged from the exhaust pipe may be collected.

Here, heat removal in the deposition shield 100 will be described. As a plasma is generated in the interior space 10s, the first deposition shield 110 is heated by the plasma. Because the gap 130 between the first and second deposition shields 110 and 120 is filled with a heat conductive medium, the heat of the first deposition shield 110 is transferred to the second deposition shield 120 via the heat conductive medium. The second deposition shield 120 is formed of metal (aluminum) having high thermal conductivity, and is in contact with the member 64 at the upper side of the outer circumferential surface of the second deposition shield 123. Therefore, the heat of the second deposition shield 120 is transferred to the member 64 (body 64m). The heat of the body 64m is transferred to the coolant flowing through the flow passage 64f.

The outer circumferential surface of the first deposition shield 110 has a rougher surface than the inner circumferential surface of the first deposition shield 110. For example, the outer circumferential surface of the first deposition shield 110 is roughened by abrasive blasting. This increases the surface area of the outer circumferential surface of the first deposition shield 110, to improve conductive property of heat from the first deposition shield 110 to the heat conductive medium. Also, the inner circumferential surface of the second deposition shield 123 is formed to be rougher than the outer circumferential surface of the second deposition shield 123. This increases the surface area of the inner circumferential surface of the second deposition shield 120 to improve conductive property of heat from the heat conductive medium to the second deposition shield 120. Further, both the outer and inner circumferential surfaces of the first deposition shield 110 and the second deposition shield 120 may be formed to be rough.

Sealing members 151 and 152 are disposed between the first and second deposition shields 110 and 120, to isolate the gap 130 from the interior space 10s. That is, the heat conductive medium is filled into the gap 130 surrounded by the first deposition shield 110, the second deposition shield 120, the sealing member 151, and the sealing member 152. This prevents the heat conductive medium filled in the gap 130 from flowing out into the interior space 10s.

Here, a tapered surface 111 is formed between the outer circumferential surface and the upper surface of the first deposition shield 110. The sealing member 151 is disposed in a space having a generally triangular cross-section formed by the tapered surface 111 of the first deposition shield 110, the inner circumferential surface of the second deposition shield 120, and the bottom surface of the heater unit 62. Similarly, a tapered surface 112 is formed on the lower side of the outer circumferential surface of the first deposition shield 110 to accommodate the sealing member 152. The sealing member 152 is disposed in a space having a generally triangular cross-section formed by the tapered surface 112 of the first deposition shield 110 and the second deposition shield 120. This sealing structure prevents the heat conductive medium filled in the gap 130 from flowing out into the interior space 10s, even if a width of the gap between the first and second deposition shields 110 and 120 is changed due to the difference in the amount of thermal expansion between the first and second deposition shields 110 and 120.

The heat conductive medium is supplied to the supply line 140 via a gas supply source 161, a mass flow controller 162, and a valve 163. Helium gas as the heat conductive medium is supplied to the gap 130 from the gas supply source 161 via the mass flow controller 162, the valve 163, and the supply line 140. When the pressure in the gap 130 detected by a pressure detector 164 reaches a predetermined pressure, the valve 163 is closed. Thus, the gap 130 is filled with helium gas. The controller 80 may monitor a state of heat transfer from the first deposition shield 110 to the second deposition shield 120, by detecting the pressure in the gap 130 using the pressure detector 164. The controller 80 may also control the state of heat transfer from the first deposition shield 110 to the second deposition shield 120, by controlling the pressure in the gap 130 by controlling the mass flow controller 162.

The structure of the deposition shield 100 has been described above. Note that the above-described structure may also be applied to the valve body 76v which opens and closes the opening 100p of the deposition shield 100. The structure of the deposition shield 100 will be further described with reference to FIG. 3. FIG. 3 is an enlarged cross-sectional view schematically illustrating a part of the plasma processing apparatus 1 according to the first embodiment. In FIG. 3, the valve body 76v and a part of the deposition shield 100 are illustrated, while other configurations are not illustrated.

As illustrated in FIGS. 1 and 3, the valve body 76v includes a first valve body 210 and a second valve body 220. Similar to the second deposition shield 120, the second valve body 220 is formed of a heat conductive material having high thermal conductivity, e.g., metal such as aluminum. The first valve body 210 is a liner disposed along an inner circumferential surface of the second valve body 220, and is formed of a material having a lower thermal conductivity than the second valve body 220, e.g., ceramic such as quartz (SiO₂), similar to the first deposition shield 110. The inner circumferential surface of the first valve body 210 is exposed to the interior space 10s in which a plasma is generated. Sealing members 251 and 252 are disposed between the first valve body 210 and the second valve body 220, so as to form a gap 230 surrounded by the first valve body 210, the second valve body 220, and the sealing members 251 and 252. In the second valve body 220 and the axial member 76s, a supply flow passage 240 extending from the gap 230 to the interior of the axial member 76s is formed. In an area in which the valve body 76v is in contact with the axial member 76s, a sealing member 253 is provided so as to encircle the supply flow passage 240. Gas (e.g., helium gas) as a heat conductive medium is supplied from the feeder 78 to the gap 230 via the axial member 76s and the supply flow passage 240, and is sealed in the gap 230. Accordingly, when heat enters from a plasma to the first valve body 210, the heat is transferred to the second valve body 220 via the heat conductive medium. The heat transferred to the second valve body 220 dissipates to the exterior of the chamber body 12 through the axial member 76s. Further, because the second valve body 220 is in contact with the second deposition shield 120, heat transferred to the second valve body 220 is transmitted to the member 64 via the second deposition shield 120, and dissipates into the coolant flowing through the flow passage 64f. Thus, by applying the above-described structure to not only the deposition shield 100 but also the valve body 76v which opens and closes the opening 100p of the deposition shield 100, the temperature of the inner wall surface surrounding the interior space 10s can be generally stabilized.

As described above, in the plasma processing apparatus 1 according to the first embodiment, heat in the first deposition shield 110 that is made of quartz is transmitted to the coolant flowing through the flow passage 64f via the heat conductive medium, the second deposition shield 120, and the member 64. This can suppress the temperature rise of the first deposition shield 110. Further, by suppressing the temperature rise of the first deposition shield 110, a difference in an amount of thermal expansion between the first deposition shield 110 and the second deposition shield 120 can be reduced. In addition, even if a shape or volume of the gap 130 varies due to the difference in the amount of thermal expansion between the first deposition shield 110 and the second deposition shield 120, because the gap 130 is filled with gas as the heat conductive medium, the shape or volume of the heat conductive medium can be changed in accordance with change in the shape or volume of the gap 130.

Here, a plasma processing apparatus according to a reference example will be described. The plasma processing apparatus according to the reference example differs in that the gap is not filled with the heat conductive medium. The plasma processing apparatus according to the reference example also differs in that the plasma processing apparatus according to the reference example is not equipped with a supply pipe and a sealing member. The other configurations are the same as that of the plasma processing apparatus 1 according to the first embodiment, and the overlapping description thereof will not be repeated.

In the plasma processing apparatus according to the reference example, because there is a large difference in an amount of thermal expansion between the first deposition shield made of quartz and the second deposition shield made of aluminum, the plasma processing apparatus according to the reference example cannot adopt a structure in which the first deposition shield is in contact with the second deposition shield, and the gap is formed between the first deposition shield and the second deposition shield. During plasma processing, the gap is an interior space atmosphere, i.e., a vacuum atmosphere. Therefore, heat transmission from the first deposition shield to the second deposition shield is accomplished by thermal radiation. Accordingly, in the plasma processing apparatus according to the reference example, as the number of substrates processed increases, the temperature of the inner wall surface of the deposition shield gradually increases due to heat from a plasma. As the temperature of the inner wall surface of the deposition shield increases, the interior space becomes a high temperature atmosphere, and plasma processing rate (e.g., etch rate) of the substrate on the support platform also varies. Thus, as the number of substrates processed increases, the plasma processing rate (e.g., etch rate) of the substrate also gradually increases.

On the other hand, in the plasma processing apparatus 1 according to the first embodiment, when heat enters from the plasma to the inner wall surface of the deposition shield 100 (first deposition shield 110), heat is transferred to the coolant in the flow passage 64f through the first deposition shield 110, the heat conductive medium, the second deposition shield 120, and the member 64. Thus, even if a large number of the substrates W is processed, the temperature of the inner wall surface of the deposition shield 100 (first deposition shield 110) can be stabilized, and the plasma processing rate (e.g., etch rate) of the substrate W can be stabilized.

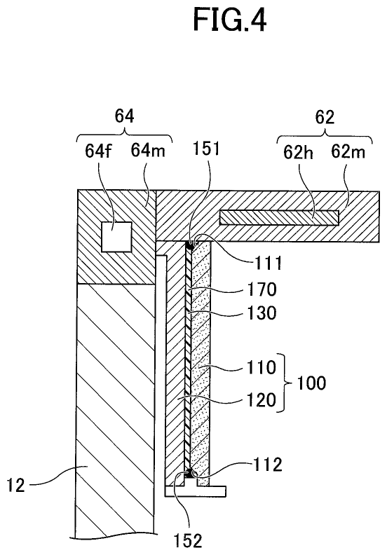

Next, a plasma processing apparatus 1 according to a second embodiment will be described with reference to FIG. 4. The plasma processing apparatus 1 according to the second embodiment differs from the plasma processing apparatus 1 according to the first embodiment in the heat conductive medium filled in the gap 130. As other configurations are the same as the configurations described in the first embodiment, overlapping descriptions are omitted.

FIG. 4 is an enlarged cross-sectional view schematically illustrating an example of a part of the plasma processing apparatus 1 according to the second embodiment. As illustrated in FIG. 4, the gap 130 is filled with an adhesive 170 as a heat conductive medium.

The adhesive 170 has high heat resistance to withstand high temperature as the heat of the plasma is transferred. Also, because the gap 130 is deformed due to the difference in the amount of thermal expansion between the first deposition shield 110 and the second deposition shield 120, the adhesive 170 has flexibility to deform in accordance with such deformation. The adhesive 170 also has good thermal conductivity as a heat conductive medium. Preferably, the adhesive 170 has low adhesive strength so that the first deposition shield 110 is replaceable.

Further, the sealing members 151 and 152 are disposed between the first deposition shield 110 and the second deposition shield 120, to isolate the gap 130 from the interior space 10s. Accordingly, this suppresses generation of a gas by reacting the adhesive 170 with highly reactive gas or plasma in the interior space 10s.

The structure of the deposition shield 100 has been described above. Note that the above-describe structure may be applied to the valve body 76v which opens and closes the opening 100p of the deposition shield 100. That is, the adhesive 170 as a heat conductive medium may be enclosed in the gap 230 surrounded by the first valve body 210 of the valve body 76v, the second valve body 220 of the valve body 76v, and the sealing members 251 and 252. In a case in which the adhesive is used as the heat conductive medium, the supply flow passage 240 may not be provided.

As described above, in the plasma processing apparatus 1 according to the second embodiment, when heat enters from the plasma to the inner wall surface of the deposition shield 100 (first deposition shield 110), heat is transferred to the coolant of the flow passage 64f through the first deposition shield 110, the adhesive 170 as the heat conductive medium, the second deposition shield 120, and the member 64. Thus, even if a large number of the substrates W is processed, the temperature of the inner wall surface of the deposition shield 100 (first deposition shield 110) can be stabilized, and the plasma processing rate (e.g., etch rate) of the substrate W can be stabilized.

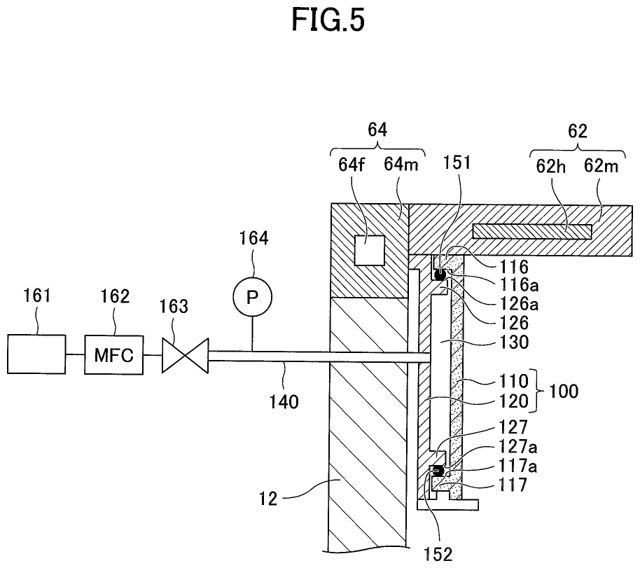

Next, a plasma processing apparatus 1 according to a third embodiment will be described with reference to FIG. 5. In the plasma processing apparatus 1 according to the third embodiment, a structure of the deposition shield 100 differs from that of the plasma processing apparatus 1 according to the first embodiment. As other configurations of the deposition shield 100 according to the third embodiment are the same as the configurations described in the first embodiment, overlapping descriptions are omitted.

FIG. 5 is an enlarged cross-sectional diagram schematically illustrating an example of a part of the plasma processing apparatus 1 according to the third embodiment.

The first deposition shield 110 includes protrusions 116 and 117. The protrusions 116 and 117 are formed so as to protrude outward in a radial direction, from the outer circumferential surface of the first deposition shield 110, which faces the second deposition shield 120. The protrusions 116 and 117 have inner surfaces 116a and 117a, respectively. As illustrated in FIG. 5, the inner surface 116a is a lower surface of the protrusion 116, the inner surface 117a is an upper surface of the protrusion 117, and the inner surface 116a faces the inner surface 117a.

The second deposition shield 120 has protrusions 126 and 127. The protrusions 126 and 127 are formed so as to protrude inward in the radial direction, from the inner circumferential surface of the second deposition shield 120, which faces the first deposition shield 110. The protrusions 126 and 127 have outer surfaces 126a and 127a, respectively. As illustrated in FIG. 5, the outer surface 126a is an upper surface of the protrusion 126, and the outer surface 127a is a lower surface of the protrusion 127.

The protrusions 126 and 127 of the second deposition shield 120 are inserted and disposed in a recess formed by the protrusions 116 and 117 of the first deposition shield 110, and by a portion of the outer circumferential surface of the first deposition shield 110 between the protrusions 116 and 117. In other words, when seen from the gap 130 (e.g. when seen from the center of the gap 130), the protrusions 116 and 117 of the first deposition shield 110 are positioned outside the protrusions 126 and 127 of the second deposition shield 120. Thus, the inner surface 116a of the protrusion 116 provided on the first deposition shield 110 and the outer surface 126a of the protrusion 126 provided on the second deposition shield 120 are positioned to face each other. The inner surface 117a of the protrusion 117 provided on the first deposition shield 110 and the outer surface 127a of the protrusion 127 provided on the second deposition shield 120 are positioned to face each other.

A sealing member 151 is disposed in a clearance between the protrusion 116 of the first deposition shield 110 and the protrusion 126 of the second deposition shield 120. That is, the sealing member 151 is disposed between the inner surface 116a of the first deposition shield 110 and the outer surface 126a of the second deposition shield 120. A sealing member 152 is also disposed in a clearance between the protrusion 117 of the first deposition shield 110 and the protrusion 127 of the second deposition shield 120. That is, the sealing member 152 is disposed between the inner surface 117a of the first deposition shield 110 and the outer surface 127a of the second deposition shield 120. In other words, the sealing members 151 and 152 are disposed outside the protrusions 126 and 127 of the second deposition shield 120.

According to the above-described arrangement, the gap 130 is sealed with the sealing members 151 and 152.

Here, the deposition shield 100 is expanded by heat of a plasma generated in the interior space 10s. The deposition shield 100 is generally cylindrical and thus expands outward by heat in the radial direction. As an amount of thermal expansion of the second deposition shield 120 formed of aluminum is larger than an amount of thermal expansion of the first deposition shield 110 formed of quartz, a thickness of the gap 130 in the radial direction (e.g., width of the gap 130 in the horizontal direction in FIG. 5) varies. Accordingly, if a sealing member is provided between the first deposition shield 110 and the second deposition shield 120 such that the sealing member is in contact with the first and second deposition shields 110 and 120 in the radial direction, the first deposition shield 110 and the second deposition shield 120 may move away from each other in the radial direction, and seal of the gap 130 may become weaker. In contrast, the sealing member 151 contacts the inner surface 116a and the outer surface 126a, and the sealing member 152 contacts the inner surface 117a the outer surface 127a, in a direction perpendicular to the radial direction (vertical direction). Although the deposition shield 100 expands by heat vertically, the deposition shield 100 expands both upward and downward, unlike thermal expansion in the radial direction. Therefore, it is possible to prevent the seal of the gap 130 from becoming weaker even if the deposition shield 100 is deformed due to thermal expansion.

Also, the protrusions 126 and 127 of the second deposition shield 120 are disposed at the recess formed between the protrusions 116 and 117 of the first deposition shield 110. An amount of thermal expansion in the vertical direction of the second deposition shield 120 formed of aluminum is greater than an amount of thermal expansion in the vertical direction of the first deposition shield 110 formed of quartz. Thus, the deposition shield 100 expands by heat in a direction that narrows the gap between the inner surface 116a and the outer surface 126a and the gap between the inner surface 117a and the outer surface 127a. That is, the deposition shield 100 expands by heat in a direction in which sealing members 151 and 152 are compressed. Thus, the deposition shield 100 can be more tightly sealed as the deposition shield 100 is deformed by thermal expansion.

Note that the structure of the deposition shield 100 is not limited to the above-described structure.

The protrusions 116 and 117 of the first deposition shield 110 may be disposed in a recess formed by the protrusions 126 and 127 of the second deposition shield 120 and a portion of the second deposition shield 120 between the protrusions 126 and 127. In this case, the sealing members may be provided at positions outside the protrusions 116 and 117 of the first deposition shield 110 and inside the protrusions 126 and 127 of the second deposition shield 120.

Alternatively, recesses may be provided on the outer circumferential surface of the first deposition shield 110 in which the protrusions 126 and 127 of the second deposition shield 123 are inserted. In such a configuration, sealing members are disposed, for example, between the outer surface 126a of the protrusion 126 and one of side walls of the recess of the first deposition shield 110 facing the outer surface 126a, and between the outer surface 127a of the protrusion 127 and the other one of the side walls of the recess of the first deposition shield 110 facing the outer surface 127a. The side walls are formed to protrude from the bottom of the recesses. That is, the side walls of the recesses can be regarded as the protrusions 116 and 117 provided on the outer circumferential surface of the first deposition shield 110. The sealing members may also be disposed between the inner surface of the protrusion 126 and one of the side walls of the recess of the first deposition shield 110 facing the inner surface of the protrusion 126, and between the inner surface of the protrusion 127 and the other one of the side walls of the recess of the first deposition shield 110 facing the inner surface of the protrusion 127.

Alternatively, recesses may be provided on the inner circumferential surface of the second deposition shield 120 in which the protrusions 116 and 117 of the first deposition shield 110 are inserted. In such a configuration, sealing members are disposed, for example, between the inner surface 116a of the protrusion 116 and one of side walls of the recesses of the second deposition shield 120 facing the inner surface 116a, and between the inner surface 117a of the protrusion 117 and the other one of the side walls of the recesses of the second deposition shield 120 facing the inner surface 117a. The side walls are formed to protrude from the bottom of the recesses. That is, the side walls can be regarded as the protrusions 126 and 127 provided on the inner circumferential surface of the second deposition shield 120. The sealing members may also be disposed between the outer surface of the protrusion 116 and one of the side walls of the recess of the second deposition shield 120 facing the outer surface of the protrusion 116, and between the outer surface of the protrusion 117 and the other one of the side walls of the recess of the second deposition shield 120 facing the outer surface of the protrusion 117.

The sealing structure of the deposition shield 100 illustrated in FIG. 5 may also be applied to the valve body 76v (see FIG. 3) having the first valve body 210 and the second valve body 220. The sealing structure of the deposition shield 100 illustrated in FIG. 5 may also be applied to the deposition shield 100 (see FIG. 4) in which the gap 130 is filled with a heat conductive medium such as an adhesive.

The embodiments of the plasma processing apparatus 1 have been described above. However, the present disclosure is not limited to the above-described embodiments, and various modifications and enhancements can be made within the scope of the gist of the present disclosure described in the claims.

The plasma processing apparatus 1 according to the first embodiment has been described as using a gas as the heat conductive medium, but this is not limited thereto. For example, the plasma processing apparatus 1 may be configured to supply, to the gap 130, liquid such as temperature-adjusted Galden (registered trademark) as the heat conductive medium. In this case, in addition to the supply line 140 for supplying liquid to the gap 130, a drain line (not illustrated) for draining liquid from the gap 130 may be provided. According to the above-described configuration, an amount of the heat conductive medium in the gap 130 can be adjusted even if the volume of the gap 130 varies due to the difference in the amount of thermal expansion between the first and second deposition shields 110 and 120.

The above embodiments have described a case in which the deposition shield 100 includes the first deposition shield 110 of quartz and the second deposition shield 120 of aluminum. However, the deposition shield 100 may only has the first deposition shield 110. In this case, the chamber body 12 also serves as the second deposition shield 120. That is, the gap 130 may be formed between the first deposition shield 110 and the inner wall surface of the chamber body 12, and the gap 130 may be filled with a heat conductive medium, such as helium gas and an adhesive.

Also, although the above embodiments have described a case in which the first deposition shield 110 is formed of quartz and the second deposition shield 120 is formed of aluminum, the first deposition shield 110 and the second deposition shield 120 are not limited thereto. The present disclosure is applicable if the first and second deposition shields 110 and 120 are formed of different materials and the first deposition shield 110 is formed of a material having lower thermal conductivity than a material of the second deposition shield 120.

The plasma processing apparatus 1 disclosed herein is applicable to any of the following types of processing apparatuses: a chemical vapor deposition (CVD) apparatus, an atomic layer deposition (ALD) apparatus, capacitively coupled plasma (CCP) type processing apparatus, an inductively coupled plasma (ICP) type processing apparatus, a processing apparatus using a radial line slot antenna (RLSA), an electron cyclotron resonance plasma (ECR) type processing apparatus, and a helicon wave plasma (HWP) type processing apparatus.

Further, the present disclosure is not limited to the plasma processing apparatus 1, but may be applied to a substrate processing apparatus (such as a thermal CVD apparatus) that does not use a plasma for processing a wafer W.

What is claimed is:

1. A substrate processing apparatus comprising:
an inner wall formed of a heat conductive material;
a quartz liner that covers the inner wall;
a first gap formed between the inner wall and the quartz liner, the first gap being filled with a first heat conductive medium;
a first sealing member provided between the inner wall and the quartz liner, to seal the first gap; and
a cooling unit that cools the inner wall.

2. The substrate processing apparatus according to claim 1, wherein
the first heat conductive medium is gas; and
the substrate processing apparatus further comprises a supply line configured to supply the gas to the first gap.

3. The substrate processing apparatus according to claim 2, further comprising a pressure detector configured to detect pressure of the gas filled in the first gap.

4. The substrate processing apparatus according to claim 1, wherein an outer circumferential surface of the quartz liner is rougher than an inner circumferential surface of the quartz liner.

5. The substrate processing apparatus according to claim 1, wherein an inner circumferential surface of the inner wall is rougher than an outer circumferential surface of the inner wall.

6. The substrate processing apparatus according to claim 1, wherein the first heat conductive medium is liquid.

7. The substrate processing apparatus according to claim 1, further comprising a supply line configured to supply the first heat conductive medium to the first gap, and a drain line configured to drain the first heat conductive medium from the first gap.

8. The substrate processing apparatus according to claim 1, wherein the first heat conductive medium is an adhesive.

9. The substrate processing apparatus according to claim 1, wherein a distance between the inner wall and the quartz liner is greater than or equal to 0.2 mm and less than or equal to 3.0 mm.

10. The substrate processing apparatus according to claim 1, wherein
an outer circumferential surface of the quartz liner includes a first protrusion;
an inner circumferential surface of the inner wall includes a second protrusion; and
the first sealing member is disposed between the first protrusion and the second protrusion.

11. The substrate processing apparatus according to claim 10, wherein, when seen from the first gap, the first protrusion is disposed outside the second protrusion.

12. The substrate processing apparatus according to claim 1, further comprising
a shutter configured to occlude an opening provided in the inner wall and the quartz liner; and
an axial member that supports the shutter; wherein
the shutter includes
a first valve body formed of quartz,
a second valve body formed of a heat conductive material,
a second gap formed between the first valve body and the second valve body, the second gap being filled with a second heat conductive medium, and
a second sealing member provided between the first valve body and the second valve body to seal the second gap; wherein the first valve body abuts the inner wall.

13. The substrate processing apparatus according to claim 12, wherein the second heat conductive medium is supplied via the axial member.

14. The substrate processing apparatus according to claim 1, wherein the inner wall is a deposition shield formed of metal.

15. The substrate processing apparatus according to claim 1, wherein the inner wall is an inner wall of a chamber.
